(19) United States
(12) Patent Application Publication
(10) Pub. No.: US 2026/0068715 A1
(43) Pub. Date: Mar. 5, 2026

(54) SEMICONDUCTOR PACKAGE

(71) Applicant: SAMSUNG ELECTRONICS CO., LTD., Suwon-si (KR)

(72) Inventors: Jihyun Lee, Suwon-si (KR); Youngbae Kim, Suwon-si (KR); DongWoon Park, Suwon-si (KR); Gyunghwan Oh, Suwon-si (KR)

(73) Assignee: SAMSUNG ELECTRONICS CO., LTD., Suwon-si (KR)

(21) Appl. No.: 19/170,777

(22) Filed: Apr. 4, 2025

(30) Foreign Application Priority Data
Sep. 2, 2024 (KR) 10-2024-0118298

(51) Int. Cl. H01L 23/498; H01L 21/48; H01L 23/00; H01L 23/14; H01L 23/538; H01L 25/18; H10B 80/00; H10D 80/30

(52) U.S. Cl. CPC H01L 23/49838; H10B 80/00; H10D 80/30

(57) ABSTRACT

A semiconductor package may include: a package substrate; an interposer on the package substrate; a first semiconductor chip on the interposer; a second semiconductor chip on the interposer; and a molding layer filling a portion between the first semiconductor chip and the second semiconductor chip, wherein the interposer includes a first pillar and a second pillar, wherein the package substrate includes a first substrate pad corresponding to the first pillar, and a second substrate pad corresponding to the second pillar, wherein the package substrate includes an insulating layer on a first portion of an upper surface of the first substrate pad and on a first portion of an upper surface of the second substrate pad, and wherein the package substrate further includes a first connection terminal between the first pillar and the first substrate pad, and a second connection terminal between the second pillar and the second substrate pad.

### CROSS-REFERENCE TO RELATED APPLICATION

This U.S. non-provisional patent application claims priority under 35 U.S.C. § 119 to Korean Patent Application No. 10-2024-0118298, filed on Sep. 2, 2024, in the Korean Intellectual Property Office, the disclosure of which is hereby incorporated by reference in its entirety.

### BACKGROUND

Embodiments of the present disclosure relate to a semiconductor package.

A semiconductor package may be provided to implement an integrated circuit chip to qualify for use in electronic products. Typically, a semiconductor package is configured such that a semiconductor chip is mounted on a printed circuit board (PCB) and bonding wires or bumps are used to electrically connect the semiconductor chip to the printed circuit board. With the development of the electronic industry, various studies are being conducted to improve the reliability of semiconductor packages.

### SUMMARY

According to embodiments of the present disclosure, a semiconductor package with improved reliability may be provided.

According to embodiments of the present disclosure, a semiconductor package may be provided and include: a package substrate; an interposer on the package substrate; a first semiconductor chip on the interposer; a second semiconductor chip on the interposer; and a molding layer filling a portion between the first semiconductor chip and the second semiconductor chip, wherein the interposer includes a first pillar and a second pillar, wherein the package substrate includes a first substrate pad corresponding to the first pillar, and a second substrate pad corresponding to the second pillar, wherein the package substrate includes an insulating layer on a first portion of an upper surface of the first substrate pad and on a first portion of an upper surface of the second substrate pad, wherein the package substrate further includes a first connection terminal between the first pillar and the first substrate pad, and a second connection terminal between the second pillar and the second substrate pad, wherein a diameter of the first pillar is smaller than a diameter of the second pillar, and wherein a diameter of a second portion of the upper surface of the first substrate pad exposed from the insulating layer is greater than a diameter of a second portion of the upper surface of the second substrate pad exposed from the insulating layer.

According to embodiments of the present disclosure, a semiconductor package may be provided and include: a package substrate; an interposer on the package substrate; a first semiconductor chip on the interposer; a second semiconductor chip on the interposer; a molding layer filling a portion between the first semiconductor chip and the second semiconductor chip, wherein the interposer includes a first pillar and a second pillar, wherein the package substrate includes a first substrate pad corresponding to the first pillar and a second substrate pad corresponding to the second pillar, wherein the package substrate further includes a first connection terminal between the first pillar and the first substrate pad, and a second connection terminal between the second pillar and the second substrate pad, wherein a diameter of the first pillar is smaller than a diameter of the second pillar, and wherein a volume of the first connection terminal is greater than a volume of the second connection terminal.

According to embodiments of the present disclosure, a semiconductor package may be provided and include: a package substrate; an interposer on the package substrate; a first semiconductor chip on the interposer; a second semiconductor chip on the interposer, and a third semiconductor chip on the interposer; and a molding layer on the first semiconductor chip, the second semiconductor chip, and the third semiconductor chip, wherein the second semiconductor chip is spaced apart from the first semiconductor chip in a first direction parallel to an upper surface of the package substrate, wherein the third semiconductor chip is spaced apart from the second semiconductor chip in a second direction perpendicular to the first direction and parallel to the upper surface of the package substrate, wherein the interposer includes a first pillar, a second pillar, and a third pillar spaced apart from each other in the first direction, wherein the second pillar is between the first pillar and the third pillar, wherein the package substrate includes a first substrate pad corresponding to the first pillar, a second substrate pad corresponding to the second pillar, and a third substrate pad corresponding to the third pillar, wherein the package substrate further includes a first connection terminal between the first pillar and the first substrate pad, a second connection terminal between the second pillar and the second substrate pad, and a third connection terminal between the third pillar and the third substrate pad, wherein a diameter of the first pillar is smaller than a diameter of the second pillar and a diameter of the third pillar, wherein the diameter of the second pillar is smaller than the diameter of the third pillar, wherein the first pillar is under a portion of the molding layer filling a gap between the first semiconductor chip and the second semiconductor chip or filling a gap between the first semiconductor chip and the third semiconductor chip, and wherein, in a plan view, a size of the first semiconductor chip is greater than a size of the second semiconductor chip and a size of the third semiconductor chip.

### BRIEF DESCRIPTION OF DRAWINGS

Example embodiments will be more clearly understood from the following detailed description taken in conjunction with the accompanying drawings. The accompanying drawings represent non-limiting example embodiments as described herein.

FIG. 1 is a plan view illustrating a semiconductor package according to some embodiments of the present disclosure.

FIG. 2 is a cross-sectional view taken along a line I-I′ of FIG. 1.

FIG. 3 is an enlarged view of an upper surface of a package substrate corresponding to a region EV1 of FIG. 1.

FIG. 4 is an enlarged view of a bottom surface of an interposer corresponding to the region EV1 of FIG. 1.

FIG. 5 is an enlarged view corresponding to a region EV2 of FIG. 2.

FIG. 6 is a view illustrating a warpage state of an interposer.

FIG. 7 is an enlarged view of an upper surface of a package substrate corresponding to the region EV1 of FIG. 1.

FIG. 8 is an enlarged view of a bottom surface of an interposer corresponding to the region EV1 of FIG. 1.

FIG. 9 is a cross-sectional view of a semiconductor package according to some embodiments.

FIG. 10 is a cross-sectional view of a semiconductor package according to some embodiments.

FIG. 11 is an enlarged view of a region EV3 of FIG. 10.

FIG. 12 is a view illustrating a warpage state of an interposer.

FIG. 13 is a cross-sectional view of a semiconductor package according to some embodiments.

FIGS. 14A, 14B, 14C, 14D, 14E, and 14G are cross-sectional views illustrating a process of forming lower preliminary connection terminals on a package substrate.

FIGS. 15A, 15B, 15C, 15D, and 15E are cross-sectional views illustrating a process of forming upper preliminary connection terminals on an interposer.

FIGS. 16A and 16B are cross-sectional views illustrating a process of mounting an interposer on a package substrate.

### DETAILED DESCRIPTION

In this specification, the same reference numerals may refer to the same components throughout the specification. A semiconductor package and a manufacturing method thereof according to non-limiting example embodiments of the present disclosure are described below.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

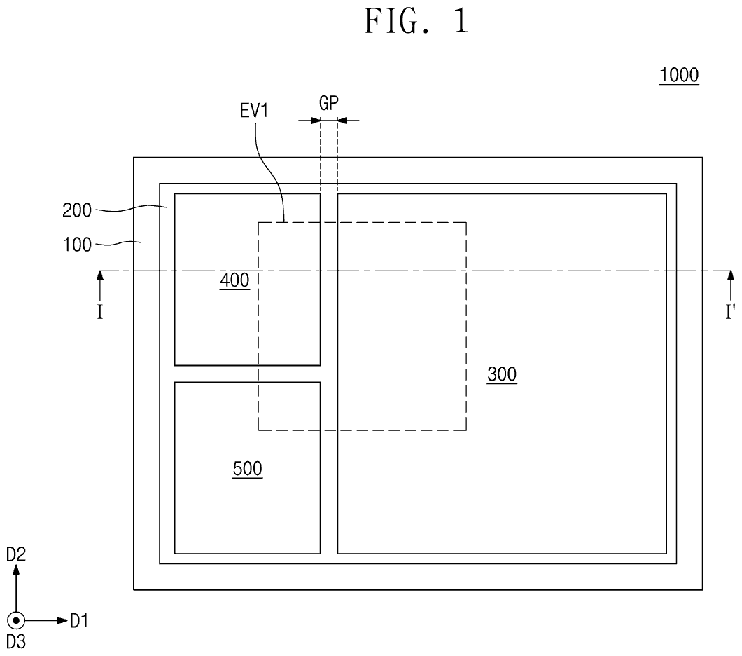

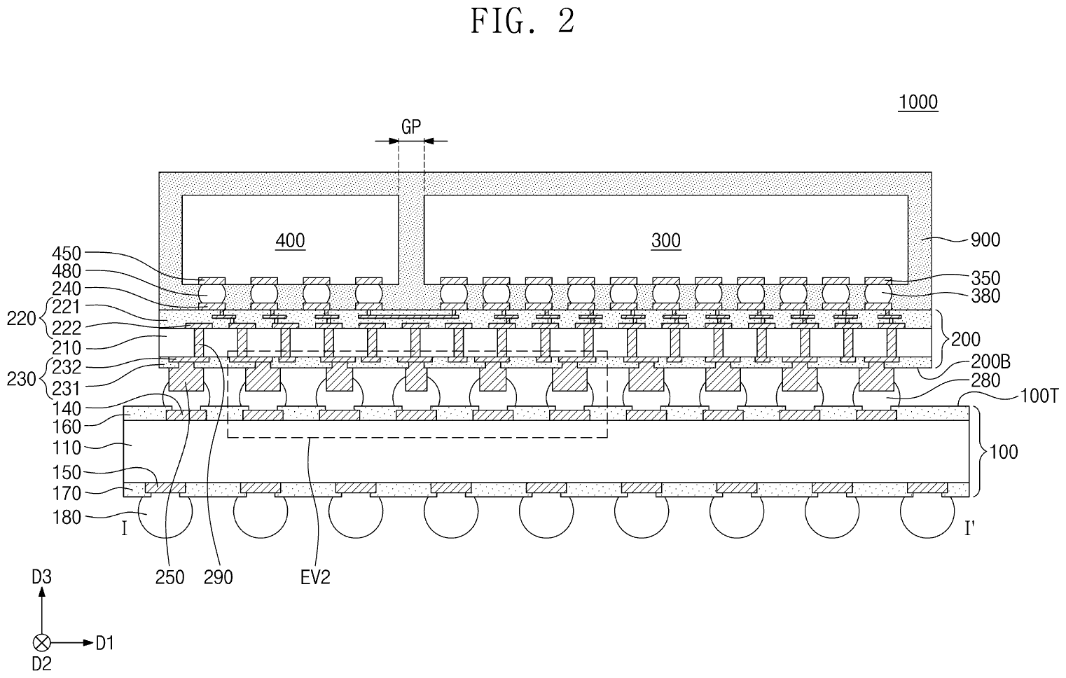

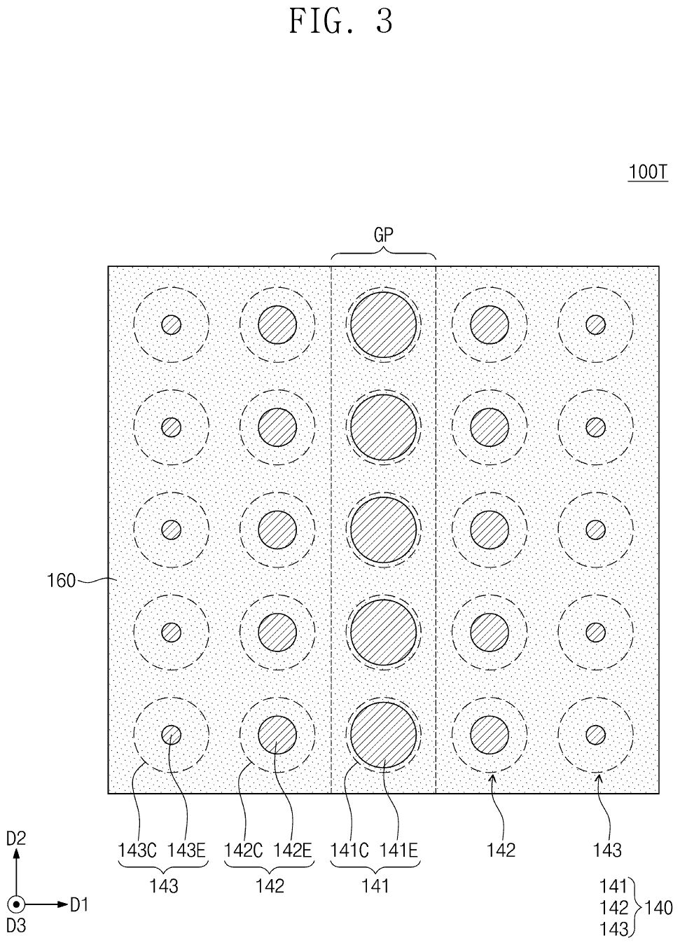

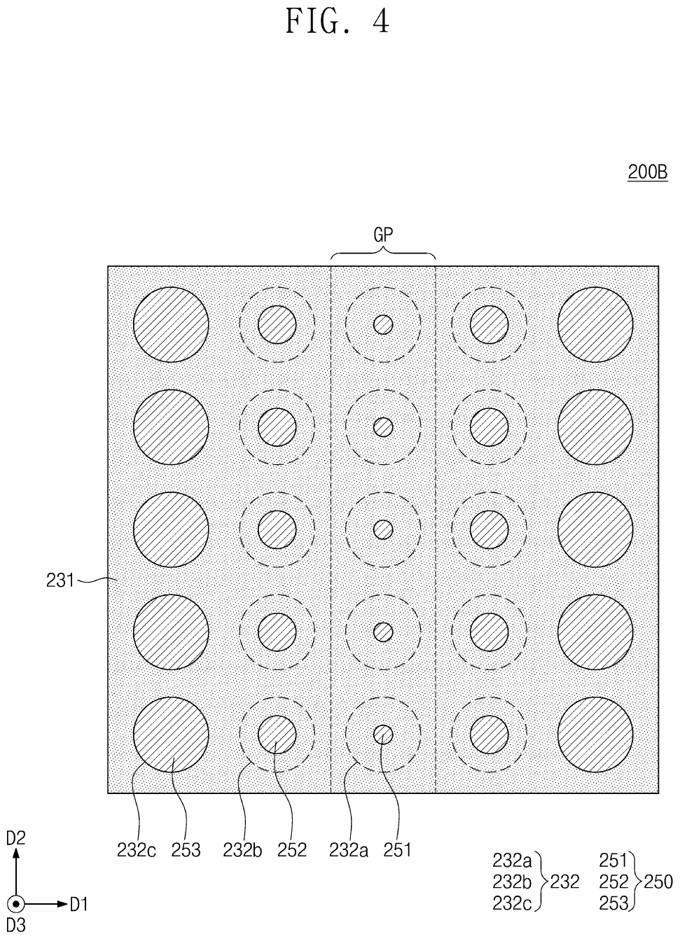

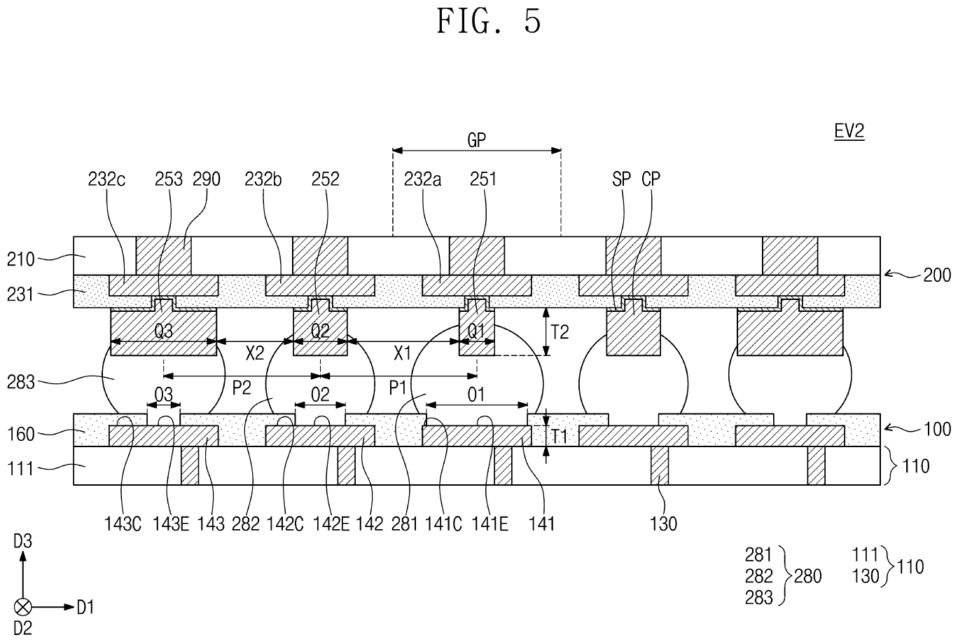

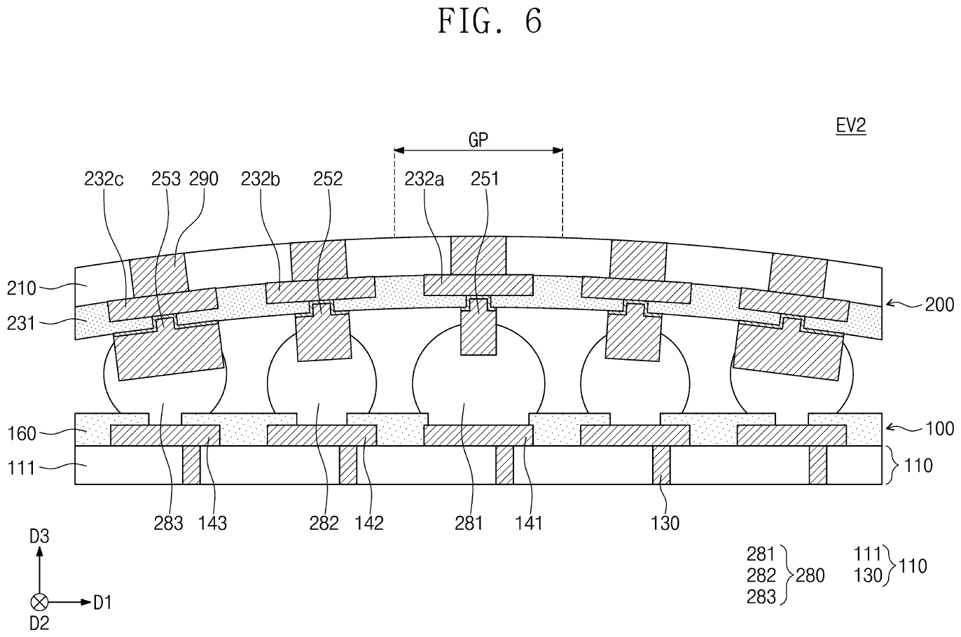

FIG. 1 is a plan view illustrating a semiconductor package according to some embodiments of the present disclosure. FIG. 2 is a cross-sectional view taken along a line I-I′of FIG. 1. FIG. 3 is an enlarged view of an upper surface of a package substrate corresponding to the region EV1 of FIG. 1. FIG. 4 is an enlarged view of a bottom surface of an interposer corresponding to the region EV1 of FIG. 1. FIG. 5 is an enlarged view corresponding to the region EV2 of FIG. 2. FIG. 6 is a view illustrating a warpage state of an interposer.

Referring to FIGS. 1 and 2, a semiconductor package 1000 may include a package substrate 100, an interposer 200, a first semiconductor chip 300, a second semiconductor chip 400, and a molding layer 900.

The package substrate 100 may be, for example, a printed circuit board (PCB). The package substrate 100 may include a wiring layer 110, a substrate upper pad 140, a substrate lower pad 150, an upper insulating layer 160, and a lower insulating layer 170. In this specification, a first direction D1 may be a direction parallel to an upper surface 100T of the package substrate 100. A second direction D2 may be a direction parallel to the upper surface 100T of the package substrate 100 and perpendicular to the first direction D1. A third direction D3 may be a direction perpendicular to the upper surface 100T of the package substrate 100.

The wiring layer 110 may include an insulating layer and a wiring structure. The wiring structure may be disposed in the insulating layer. For example, the insulating layer may include a composite of glass fiber and epoxy resin. The wiring structure may include wiring lines disposed in different layers and vias connecting the wiring lines. The wiring structure may include a metal material such as, for example, copper. The wiring structure may connect the substrate upper pad 140 and the substrate lower pad 150.

A plurality of the substrate upper pads 140 may be disposed on an upper surface of the wiring layer 110. A plurality of the substrate lower pads 150 may be disposed on a lower surface of the wiring layer 110. Each of the substrate upper pad 140 and the substrate lower pad 150 may include a metal material such as copper.

The upper insulating layer 160 may be disposed on the upper surface of the wiring layer 110. The upper insulating layer 160 may include, for example, a solder resist. The upper insulating layer 160 may be, for example, a solder resist layer. The upper insulating layer 160 may cover a side surface of each of the substrate upper pads 140 and may cover a portion of an upper surface of each of the substrate upper pads 140.

The lower insulating layer 170 may be disposed on a lower surface of the wiring layer 110. The lower insulating layer 170 may be, for example, a solder resist layer. The lower insulating layer 170 may cover a side surface of each of the substrate lower pads 150 and may cover a portion of a lower surface of each of the substrate lower pads 150.

External connection terminals 180 may be disposed on a lower surface of each of the substrate lower pads 150. Each of the external connection terminals 180 may have, for example, a ball shape including solder.

The interposer 200 may be disposed on the upper surface 100T of the package substrate 100. The interposer 200 may have a structure similar to a silicon interposer.

The interposer 200 may include a semiconductor substrate 210, an upper wiring layer 220, a through via 290, and a lower wiring layer 230.

The semiconductor substrate 210 may include, for example, one from among a silicon substrate, a germanium substrate, and a silicon-germanium substrate.

The upper wiring layer 220 may be disposed on an upper surface of the semiconductor substrate 210. The upper wiring layer 220 may include a first insulating layer 221, a first wiring structure 222, and an upper bonding pad 240. The first insulating layer 221 may include an insulating material such as silicon oxide, silicon nitride, and/or silicon oxynitride. The first wiring structure 222 may be disposed in the first insulating layer 221. The first wiring structure 222 may include wiring lines disposed in different layers and vias connecting the wiring lines. The first wiring structure 222 may include a metal material such as copper, aluminum, nickel, and/or gold. Through the first wiring structure 222, the first semiconductor chip 300 and the second semiconductor chip 400 may be electrically connected to each other. The upper bonding pad 240 may be disposed on the first wiring structure 222 and may be exposed from the first insulating layer 221.

The lower wiring layer 230 may be disposed on a lower surface of the semiconductor substrate 210. The lower wiring layer 230 may include a second insulating layer 231, a second wiring structure 232, and a pillar 250. The second insulating layer 231 may include an insulating material such as silicon oxide, silicon nitride, and/or silicon oxynitride. The second wiring structure 232 may include wiring lines disposed in different layers and vias connecting the wiring lines. According to some embodiments, the wiring lines may not be disposed in multiple layers, but may be disposed only in one layer that is in contact with the through via 290. In this case, the lower wiring layer 230 may not include a via connecting the wiring lines. The second wiring structure 232 may include a metal material such as copper, aluminum, nickel, and/or gold.

The pillar 250 may be disposed under the second wiring structure 232 and may be exposed from the second insulating layer 231. The wiring line in contact with the pillar 250 may act as a pad. The pillar 250 may have a shape protruding from the second insulating layer 231.

Internal connection terminals 280 may be interposed between a plurality of the pillars 250 and the substrate upper pads 140. Each of the internal connection terminals 280 may include a metal material such as solder.

The first semiconductor chip 300 and the second semiconductor chip 400 may be disposed on the interposer 200. The first semiconductor chip 300 and the second semiconductor chip 400 may be spaced apart from each other in the first direction D1. The first semiconductor chip 300 and the second semiconductor chip 400 may be different types of chips from each other. For example, the first semiconductor chip 300 may be, for example, a logic chip, and the second semiconductor chip 400 may be, for example, a memory chip. The first semiconductor chip 300 may be, for example, an application-specific integrated circuit (ASIC), and the second semiconductor chip 400 may be, for example, a dynamic random-access memory (DRAM). When viewed in a plan view, a size of the first semiconductor chip 300 may be greater than a size of the second semiconductor chip 400.

The first semiconductor chip 300 may include a first chip pad 350. A first connection terminal 380 may be interposed between the first chip pad 350 and the upper bonding pad 240. The second semiconductor chip 400 may include a second chip pad 450. A second connection terminal 480 may be disposed between the second chip pad 450 and the upper bonding pad 240. Each of the first connection terminal 380 and the second connection terminal 480 may include a conductive material such as solder.

The molding layer 900 may be disposed on the interposer 200. The molding layer 900 may cover an upper surface and side surfaces of the first semiconductor chip 300, an upper surface and side surfaces of the second semiconductor chip 400, and may fill a space between a plurality of the first connection terminals 380, between a plurality of the second connection terminals 480, and between side surfaces of the first semiconductor chip 300 and the second semiconductor chip 400. A gap GP may be between the side surfaces of the first semiconductor chip 300 and the second semiconductor chip 400, and the molding layer 900 may fill the gap GP. The molding layer 900 may include, for example, an epoxy molding compound (EMC).

The semiconductor package 1000 according to an embodiment of the present disclosure may further include a third semiconductor chip 500, as shown in FIG. 1. The third semiconductor chip 500 may be a different type of semiconductor chip from the first semiconductor chip 300. The third semiconductor chip 500 may be the same type of chip as the second semiconductor chip 400 or a different type of chip. The third semiconductor chip 500 may be, for example, a DRAM. The molding layer 900 may cover an upper surface and side surfaces of the third semiconductor chip 500. Connection terminals may be disposed between the third semiconductor chip 500 and the interposer 200, and the molding layer 900 may fill a space between the connection terminals. A gap GP may be between side surfaces of the first semiconductor chip 300 and the third semiconductor chip 500, and the molding layer 900 may fill the gap GP.

Referring to FIGS. 1, 2, 3, 4, and 5, the substrate upper pads 140 may be arranged from each other in the first direction D1 and the second direction D2 on an upper surface 100T of the package substrate 100.

The substrate upper pads 140 may include first substrate pads 141, second substrate pads 142, and third substrate pads 143 spaced apart from each other in the first direction D1. Each of the first substrate pads 141, the second substrate pads 142, and the third substrate pads 143 may have substantially the same diameter as each other. The first substrate pads 141 may overlap with the gap GP between the first semiconductor chip 300 and the second semiconductor chip 400, and the gap GP between the first semiconductor chip 300 and the third semiconductor chip 500 in the third direction D3. That is, the first substrate pads 141 may be disposed under the gap GP between the first semiconductor chip 300 and the second semiconductor chip 400 and/or the gap GP between the first semiconductor chip 300 and the third semiconductor chip 500. The second substrate pads 142 may be disposed between the first substrate pad 141 and the third substrate pad 143. When viewed in a plan view, the first substrate pads 141 may be positioned at a center of the package substrate 100 or closer than the second substrate pads 142 and the third substrate pads 143 to the center. A plurality of the first substrate pads 141, a plurality of the second substrate pads 142, and a plurality of the third substrate pads 143 may be provided and may be arranged in the second direction D2 from each other.

The upper insulating layer 160 may cover a side surface and a portion of the upper surface of the first substrate pad 141, a side surface and a portion of the upper surface of the second substrate pad 142, and a side surface and a portion of the upper surface of the third substrate pad 143. The upper surface of the first substrate pad 141 may include a first exposed part 141E and a first covered part 141C. The upper surface of the second substrate pad 142 may include a second exposed part 142E and a second covered part 142C. The third substrate pad 143 may include a third exposed part 143E and a third covered part 143C. The first exposed part 141E, the second exposed part 142E, and the third exposed part 143E may be portions of the upper surface of the first substrate pad 141, the upper surface of the second substrate pad 142, and the upper surface of the third substrate pad 143, respectively, which are exposed from the upper insulating layer 160. The first covered part 141C, the second covered part 142C, and the third covered part 143C may be portions of the upper surface of the first substrate pad 141, the upper surface of the second substrate pad 142, and the upper surface of the third substrate pad 143, respectively, which are covered by the upper insulating layer 160.

An area of the first exposed part 141E may be greater than an area of the second exposed part 142E and an area of the third exposed part 143E. The area of the second exposed part 142E may be greater than the area of the third exposed part 143E. When viewed in a plan view, each of the first exposed part 141E, the second exposed part 142E, and the third exposed part 143E may have a circular shape. The first exposed part 141E may have a first exposed diameter O1, the second exposed part 142E may have a second exposed diameter O2, and the third exposed part 143E may have a third exposed diameter O3. The first exposed diameter O1 may be greater than the second exposed diameter O2 and the third exposed diameter O3. The second exposed diameter O2 may be greater than the third exposed diameter O3. For example, the first exposed diameter O1 may be four times the third exposed diameter O3, and the second exposed diameter O2 may be twice the third exposed diameter O3. The first exposed diameter O1 may be at least four times the third exposed diameter O3, and the second exposed diameter O2 may be at least twice and less than four times the third exposed diameter O3.

Pillars 250 on a lower surface 200B of the interposer 200 may include a first pillar 251, a second pillar 252, and a third pillar 253 spaced apart from each other in the first direction D1. The second wiring structure 232 may include a first connection pad 232a, a second connection pad 232b, and a third connection pad 232c spaced apart from each other in the first direction D1. The first pillar 251 may be disposed below and in contact with the first connection pad 232a. The second pillar 252 may be disposed below and in contact with the second connection pad 232b. The third pillar 253 may be disposed below and in contact with the third connection pad 232c. The first connection pad 232a, the second connection pad 232b, and the third connection pad 232c may be electrically connected to a plurality of the through vias 290. The first pillar 251, the second pillar 252, and the third pillar 253 may be electrically connected to the through vias 290 by the first connection pad 232a, the second connection pad 232b, and the third connection pad 232c, respectively. Each of the first connection pad 232a, the second connection pad 232b, and the third connection pad 232c may be in contact with the through vias 290. Alternatively, wiring lines and vias connecting the wiring lines may be interposed between the first connection pad 232a, the second connection pad 232b, and the third connection pad 232c and the through vias 290. A diameter of each of the first connection pad 232a, the second connection pad 232b, and the third connection pad 232c may be substantially the same as each other.

The first pillar 251 and the first connection pad 232a may overlap with the gap GP between the first semiconductor chip 300 and the second semiconductor chip 400 in the third direction D3. That is, the first pillar 251 and the first connection pad 232a may be disposed below the gap GP between the first semiconductor chip 300 and the second semiconductor chip 400. The second pillar 252 may be disposed between the first pillar 251 and the third pillar 253. When viewed in a plan view, the first pillar 251 may be positioned at a center of the interposer 200 or closer than the second pillar 252 and the third pillar 253 to the center. A plurality of first pillars 251, a plurality of second pillars 252, and a plurality of third pillars 253 may be provided and arranged with respect to each other in the second direction D2. A thickness T2 of each of the first pillar 251, the second pillar 252, and the third pillar 253 in, for example, the third direction D3, may be substantially the same.

A thickness of each of the first pillar 251, the second pillar 252, and the third pillar 253 may be a distance to the lower surface of the first pillar 251, a distance to the lower surface of the second pillar 252, and a distance to the lower surface of the third pillar 253 from the lower surface of the second insulating layer 231. For example, the thickness T2 of each of the first pillar 251, the second pillar 252, and the third pillar 253 may be greater than a thickness T1 of each of the first substrate pad 141, the second substrate pad 142, and the third substrate pad 143.

The first pillar 251, the second pillar 252, and the third pillar 253 may have a cylinder or a cylinder-like shape. Each of the first pillar 251, the second pillar 252, and the third pillar 253 may have a circular shape when viewed in a plan view.

The first pillar 251 may have a first diameter Q1, the second pillar 252 may have a second diameter Q2, and the third pillar 253 may have a third diameter Q3. The first diameter Q1 may be smaller than the second diameter Q2 and the third diameter Q3. The second diameter Q2 may be smaller than the third diameter Q3. For example, the first diameter Q1 may be ¼ of the third diameter Q3, and the second diameter Q2 may be ½ of the third diameter Q3. The first diameter Q1 may be ¼ or less of the third diameter Q3, and the second diameter Q2 may be ½ or less of the third diameter Q3, and may be greater than ¼ of the third diameter Q3.

A first pitch P1 between the first pillar 251 and the second pillar 252 and a second pitch P2 between the second pillar 252 and the third pillar 253 may be substantially the same as each other. A first separation distance X1 between the first pillar 251 and the second pillar 252 may be greater than a second separation distance X2 between the second pillar 252 and the third pillar 253. The first pitch P1 may be the sum of half the first diameter Q1, half the second diameter Q2, and the first separation distance X1. The second pitch P2 may be the sum of half the second diameter Q2, half the third diameter Q3, and the second separation distance X2.

Each of the first pillar 251, the second pillar 252, and the third pillar 253 may include a seed pattern SP and a conductive pattern CP. The seed pattern SP may include at least one from among titanium, tungsten, and copper. The conductive pattern CP may include, for example, copper. The conductive pattern CP may be disposed on the seed pattern SP. The seed pattern SP may be in contact with the second insulating layer 231, the first connection pad 232a, the second connection pad 232b, and the third connection pad 232c.

The internal connection terminals 280 may include a first internal connection terminal 281, a second internal connection terminal 282, and a third internal connection terminal 283 spaced apart from each other in the first direction D1. The first internal connection terminal 281 may be interposed between the first pillar 251 and the first substrate pad 141. The second internal connection terminal 282 may be interposed between the second pillar 252 and the second substrate pad 142. The third internal connection terminal 283 may be interposed between the third pillar and the third substrate pad 143.

The first internal connection terminal 281 may be in contact with a lower surface and a side surface of the first pillar 251, the first exposed part 141E of the first substrate pad 141, and the upper surface of the upper insulating layer 160. The second internal connection terminal 282 may be in contact with a lower surface and a side surface of the second pillar 252, the second exposed part 142E of the second substrate pad 142, and the upper surface of the upper insulating layer 160. The third internal connection terminal 283 may be in contact with a lower surface and a side surface of the third pillar 253, the third exposed part 143E of the third substrate pad 143, and the upper surface of the upper insulating layer 160.

A volume of the first internal connection terminal 281 may be greater than a volume of the third internal connection terminal 283. For example, the volume of the first internal connection terminal 281 may be 326038.4 m³, and the volume of the third internal connection terminal 283 may be 147114.9 m³.

FIG. 6 is a view illustrating a warpage state of an interposer.

Referring to FIG. 6, as will be described later, the interposer 200 may be mounted on the package substrate 100 to form the semiconductor package 1000 according to an embodiment of the present disclosure. A process of mounting the interposer 200 on the package substrate 100 may be performed at a high temperature (e.g., 200° C. to 300° C.). In this case, due to a difference in thermal expansion coefficients of semiconductor materials forming most of the first semiconductor chip 300 and the second semiconductor chip 400 and a thermal expansion coefficient of the molding layer, warpage may occur significantly in the gap GP between the first semiconductor chip 300 and the second semiconductor chip 400.

According to embodiments of the present disclosure, a diameter of the first pillar 251 may be small, and a volume of the solder of the first internal connection terminal 281 may be large. Even when a “reversed U” shaped warpage occurs in the interposer 200 and the first pillar 251 moves upward relative to the other pillars, sufficient solder may be attached to the side surface of the first pillar 251 with a small diameter. As a result, a non-wet phenomenon in which the first internal connection terminal 281 does not attach to the first pillar 251 may be prevented. In addition, a short circuit in which the first pillar 251 and the first substrate pad 141 are not electrically connected due to a crack in the first internal connection terminal 281 may also be prevented.

According to embodiments of the present disclosure, as the first internal connection terminal 281 may be formed on the side surface and the lower surface of the first pillar 251, allowable warpage may also increase compared to when the first internal connection terminal 281 is formed only on the lower surface of the first pillar 251. The allowable warpage refers to allowable degree of warpage that does not cause a short circuit or a non-wetting phenomenon even when the warpage occurs.

That is, the small diameter of the first pillar 251 and the large volume of the first internal connection terminal 281 as described above may allow the prevention of the non-wetting phenomenon, the prevention of the short circuit, and the increase in the allowable warpage, thereby increasing reliability of the semiconductor package.

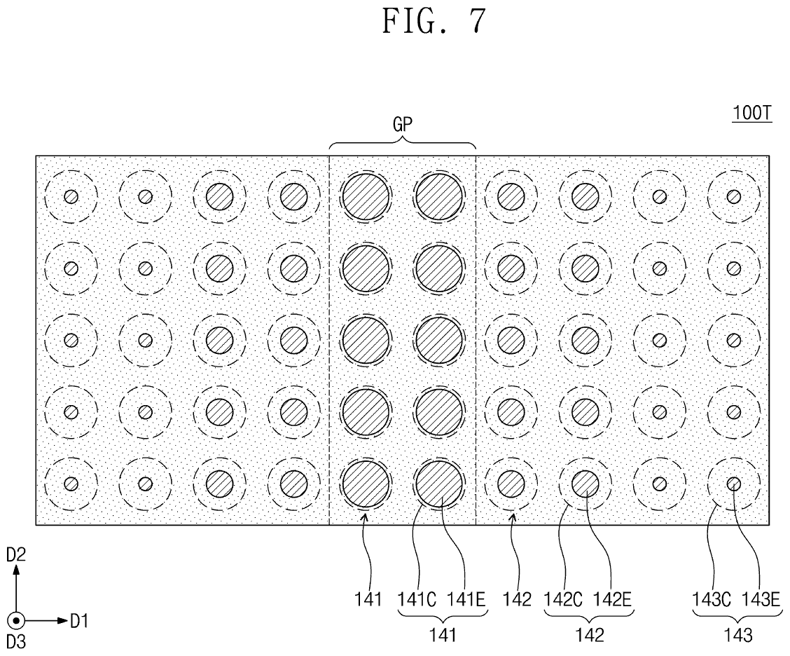

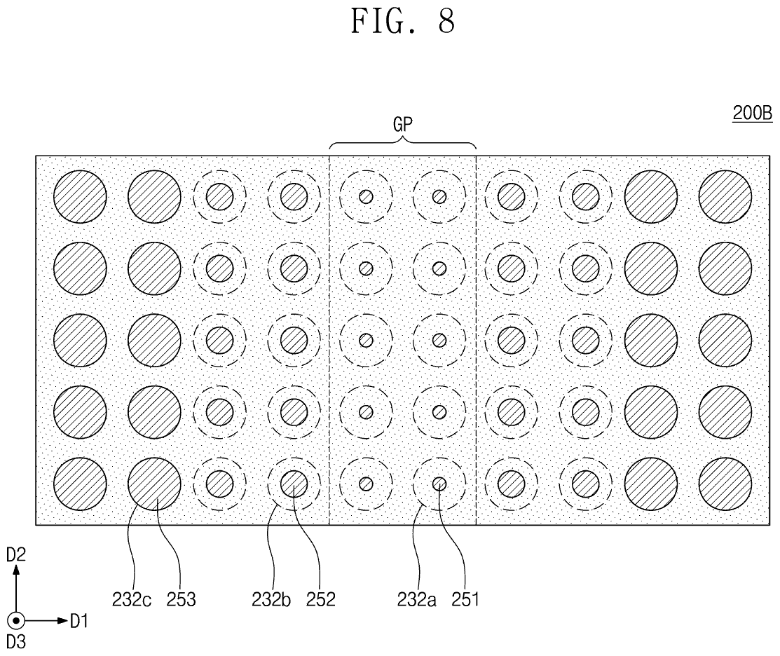

FIG. 7 is an enlarged view of an upper surface of a package substrate corresponding to the region EV1 of FIG. 1. FIG. 8 is an enlarged view of a bottom surface of an interposer corresponding to the region EV1 of FIG. 1. Except for what is described below, descriptions duplicate with what is described with reference to FIGS. 3 and 4 may be omitted.

Referring to FIG. 7, a plurality of first substrate pads 141 may be provided in the first direction D1. The first substrate pads 141 may be arranged in the first direction D1 and the second direction D2. The first substrate pads 141 may overlap with the gap GP in the third direction D3. Similarly, a plurality of second substrate pads 142 and a plurality of third substrate pads 143 may be provided in the first direction D1. The second substrate pads 142 and the third substrate pads 143 may be arranged in the first direction D1 and the second direction D2.

Referring to FIG. 8, a plurality of first pillars 251 may be provided in the first direction D1. The first pillars 251 may be arranged in the first direction D1 and the second direction D2. The first pillars 251 may overlap with the gap GP in the third direction D3. Similarly, a plurality of second pillars 252 and a plurality of third pillars 253 may be provided in the first direction D1. The second pillars 252 and the third pillars 253 may be arranged in the first direction D1 and the second direction D2.

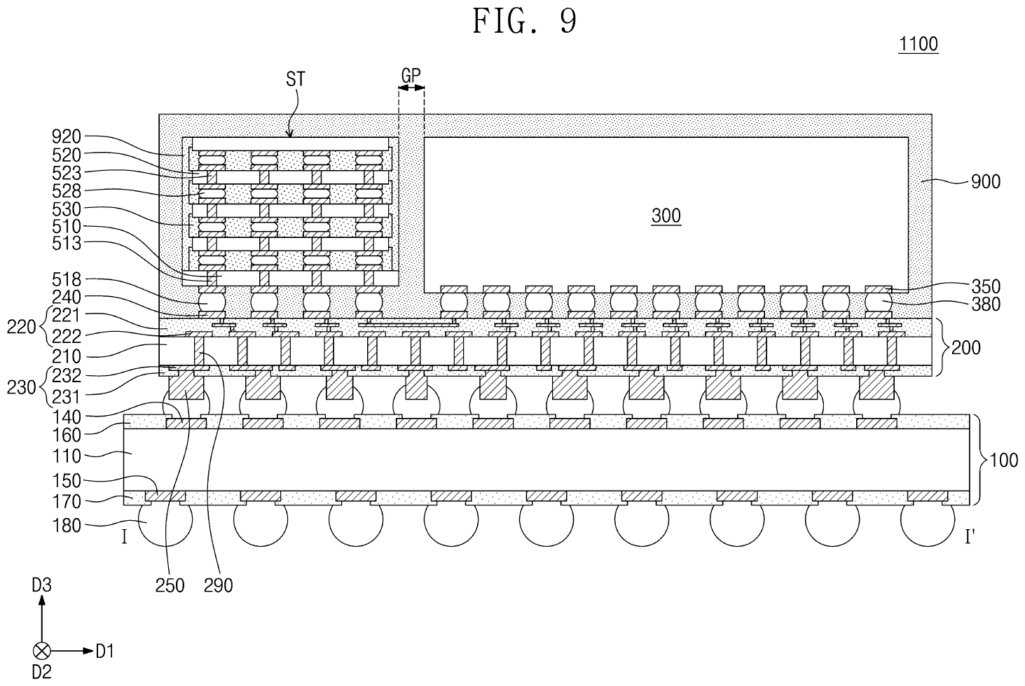

FIG. 9 is a cross-sectional view of a semiconductor package according to some embodiments. Description overlapping with descriptions made with reference to FIGS. 1 to 6 may be omitted.

Referring to FIG. 9, a semiconductor package 1100 may include at least one chip stack structure ST. In place of the second semiconductor chip 400 and the third semiconductor chip 500 of FIGS. 1 and 2, chip stack structures ST may be disposed. The chip stack structure ST may also be a high bandwidth memory (HBM).

The chip stack structure ST may include a buffer chip 510, memory chips 520, a second molding layer 920, and adhesive layers 530. The buffer chip 510 may be a logic chip and may perform an interface function. The memory chips 520 may be disposed on the buffer chip 510. The memory chips 520 may be stacked in the third direction D3. The buffer chip 510 may include a first penetration electrode 513, and the memory chips 520 may include a second penetration electrode 523. A first micro bump 518 may be interposed between the buffer chip 510 and the interposer 200. Second micro bumps 528 may be interposed between the buffer chip 510 and an adjacent one of the memory chips 520, and between the memory chips 520. The first micro bump 518 and the second micro bumps 528 may include, for example, solder. The adhesive layers 530 may be interposed between the buffer chip 510 and the adjacent one of the memory chips 520, and between the memory chips 520. The adhesive layers 530 may be, for example, a non-conductive film (NCF). The second molding layer 920 may cover an upper surface of the buffer chip 510, side surfaces of the memory chips 520, and side surfaces of the adhesive layers 530. The second molding layer 920 may include, for example, an epoxy molding compound. The molding layer 900 may also be referred to as a first molding layer, and the first molding layer may cover the chip stack structure ST.

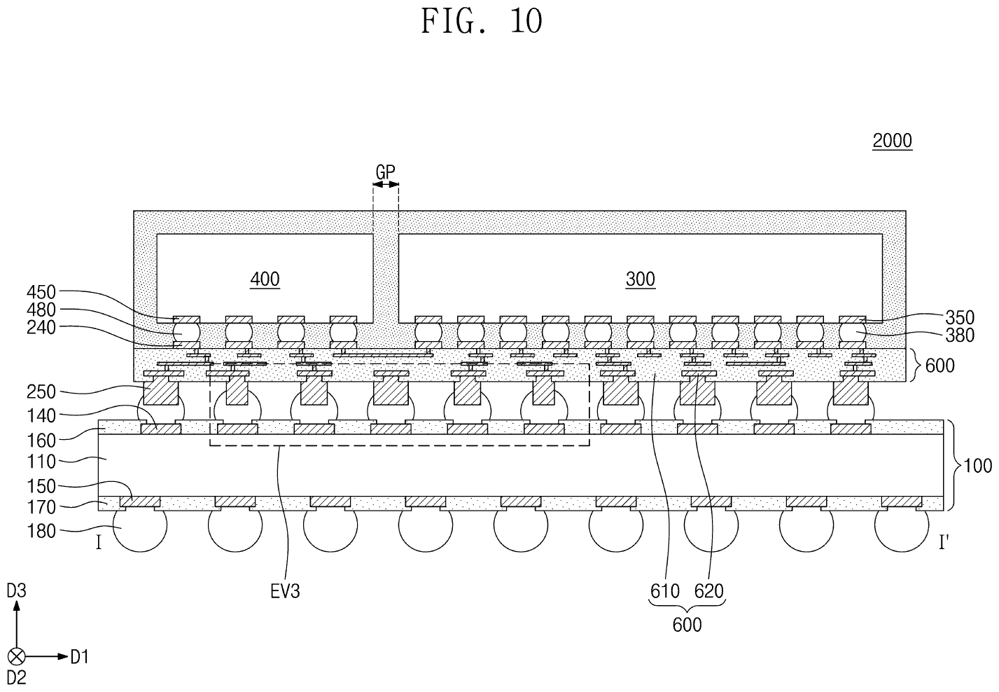

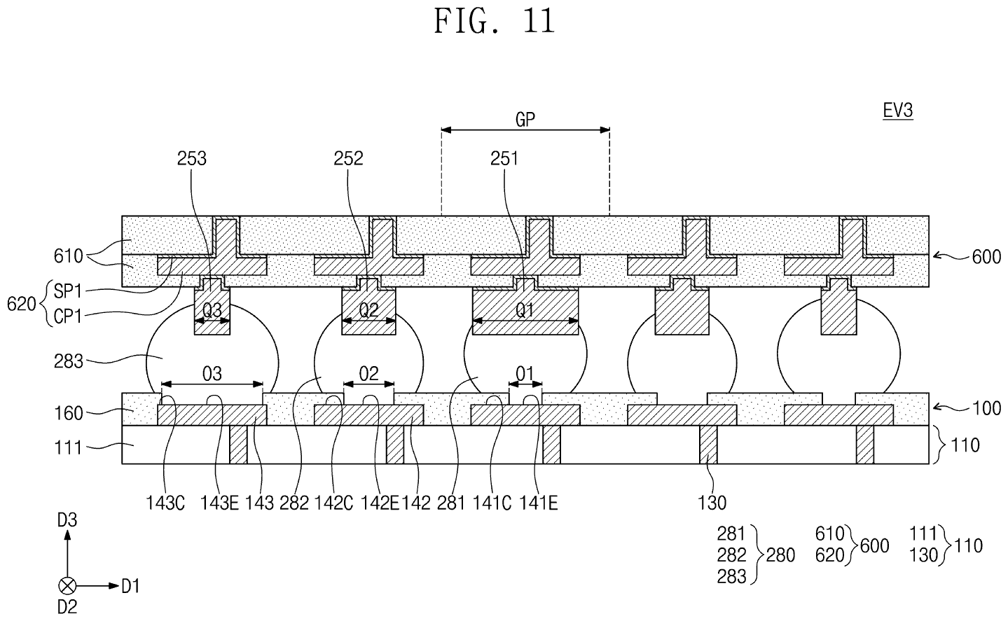

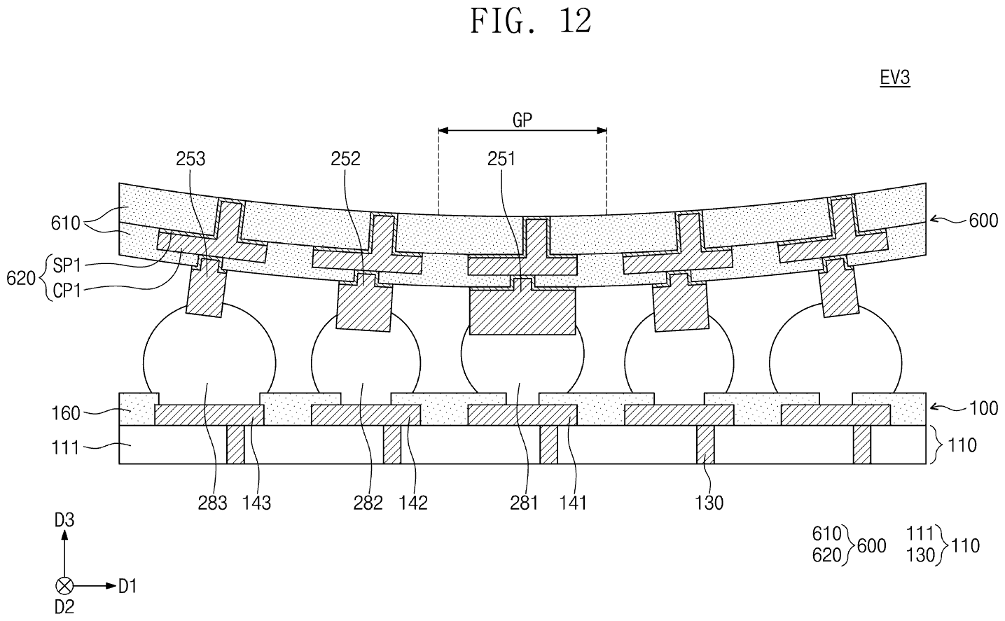

FIG. 10 is a cross-sectional view of a semiconductor package according to some embodiments. FIG. 11 is an enlarged view of a region EV3 of FIG. 10. FIG. 12 is a view illustrating a warpage state of an interposer. Description overlapping with descriptions made with reference to FIGS. 1 to 6 may be omitted.

Referring to FIGS. 10 and 11, a semiconductor package 2000 may include a redistribution interposer 600. The redistribution interposer 600 may include a different configuration from the interposer 200. For example, the redistribution interposer 600 may include a polymer insulating layer 610 and a redistribution pattern 620 in the polymer insulating layer 610. That is, unlike a silicon interposer, the redistribution interposer 600 may not include a semiconductor substrate and a penetration electrode. The polymer insulating layer 610 may include a photosensitive insulating material such as polyimide, epoxy, acrylic, and/or benzocyclobutane (BCB). The redistribution pattern 620 may include a redistribution line portion and a via portion. The redistribution pattern 620 may include a seed pattern SP1 and a conductive pattern CP1. The seed pattern SP1 may include at least one from among titanium, tungsten, and copper. The conductive pattern CP1 may include, for example, copper. The conductive pattern CP1 may be disposed on the seed pattern SP1. The first semiconductor chip 300, the second semiconductor chip 400, and the third semiconductor chip 500 may be electrically connected to each other through the redistribution interposer 600, and may also be electrically connected to the package substrate 100.

The area of the third exposed part 143E may be greater than the area of the second exposed part 142E and the area of the first exposed part 141E. The area of the second exposed part 142E may be greater than the area of the first exposed part 141E. The third exposed diameter O3 may be greater than the second exposed diameter O2 and the first exposed diameter O1. The second exposed diameter O2 may be greater than the first exposed diameter O1. For example, the first exposed diameter O1 may be ¼ of the third exposed diameter O3, and the second exposed diameter O2 may be ½ of the third exposed diameter O3. The redistribution pattern 620 in contact with the first pillar 251, the second pillar 252, and the third pillar 253 may serve as the connection pads (e.g., the first connection pad 232a, the second connection pad 232b, and the third connection pad 232c) described above. The third diameter Q3 may be smaller than the second diameter Q2 and the first diameter Q1. The second diameter Q2 may be smaller than the first diameter Q1. For example, the third diameter Q3 may be ¼ of the first diameter Q1, and the second diameter Q2 may be ½ of the first diameter Q1. A volume of the third internal connection terminal 283 may be greater than a volume of the first internal connection terminal 281.

FIG. 12 is a view illustrating a warpage state of a redistribution interposer.

Referring to FIG. 12, during the process of mounting the redistribution interposer 600 on the package substrate 100, a “U”-shaped warpage may occur in the redistribution interposer 600. The first pillar 251 may move downward relative to the other pillars, and the third pillar 253 may move upward relative to the other pillars. In this case, non-wet phenomenon in which the third internal connection terminal 283 does not attach to the third pillar 253 may be prevented, and crack and short circuit of the third internal connection terminal 283 may be prevented.

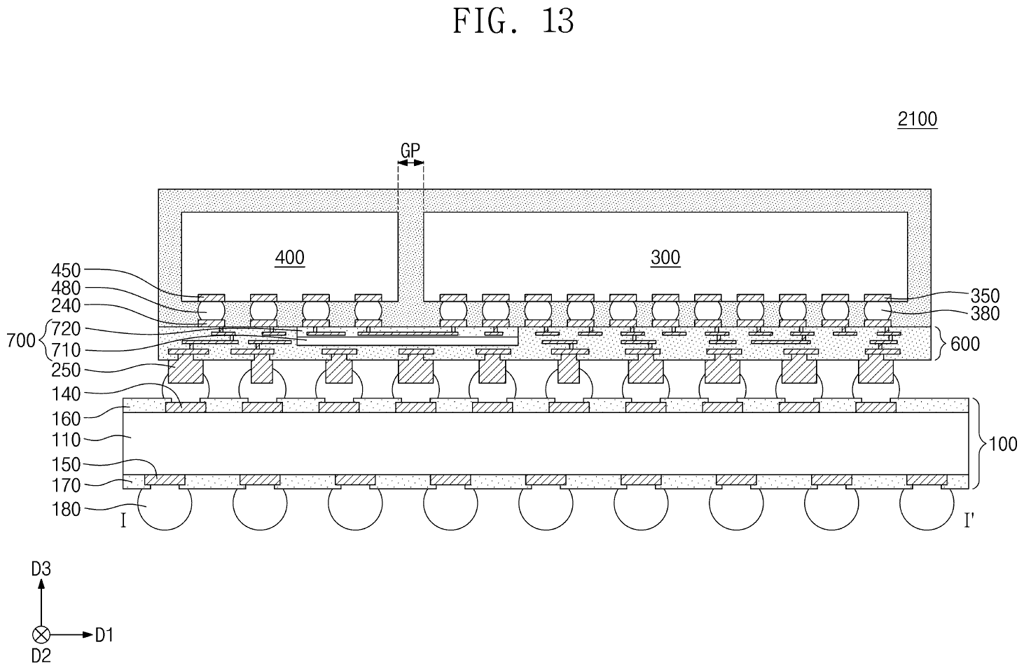

FIG. 13 is a cross-sectional view of a semiconductor package according to some embodiments. Description overlapping with descriptions made with reference to FIGS. 10 to 12 may be omitted.

A semiconductor package 2100 according to FIG. 13 may have a connection die 700 disposed in the redistribution interposer 600. The connection die 700 may be a bridge. The connection die 700 may include a semiconductor substrate 710 and a connection wiring layer 720. The first semiconductor chip 300, the second semiconductor chip 400, and the third semiconductor chip 500 may be electrically connected to each other through the connection die 700. The first semiconductor chip 300, the second semiconductor chip 400, and the third semiconductor chip 500 may be electrically connected to the package substrate 100 through the redistribution interposer 600.

Even when the connection die 700 is disposed in the redistribution interposer 600, the redistribution interposer 600 may have a structure as described with reference FIG. 11.

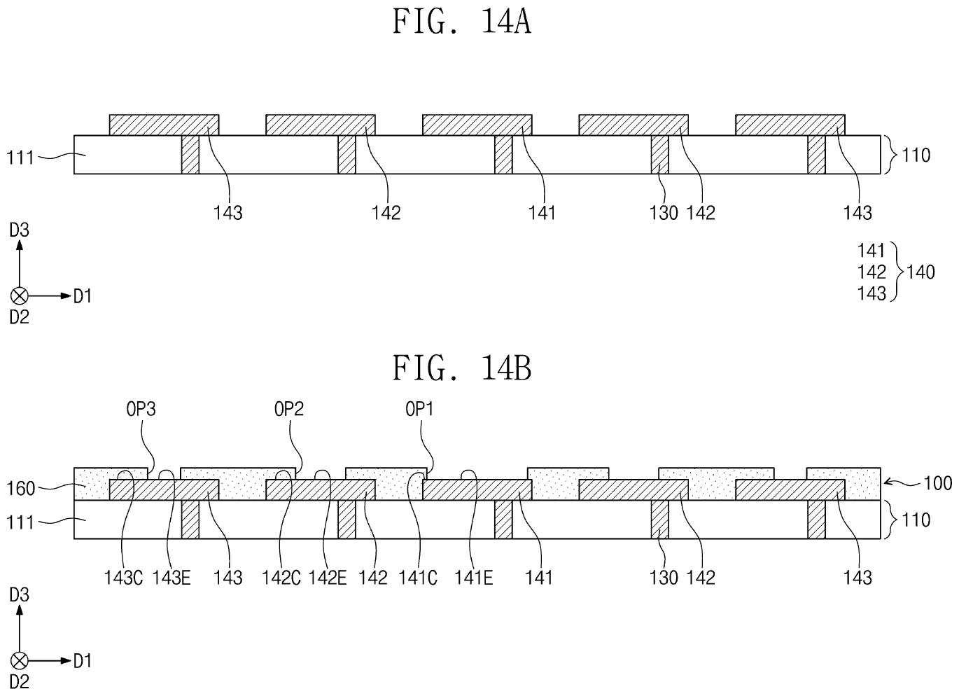

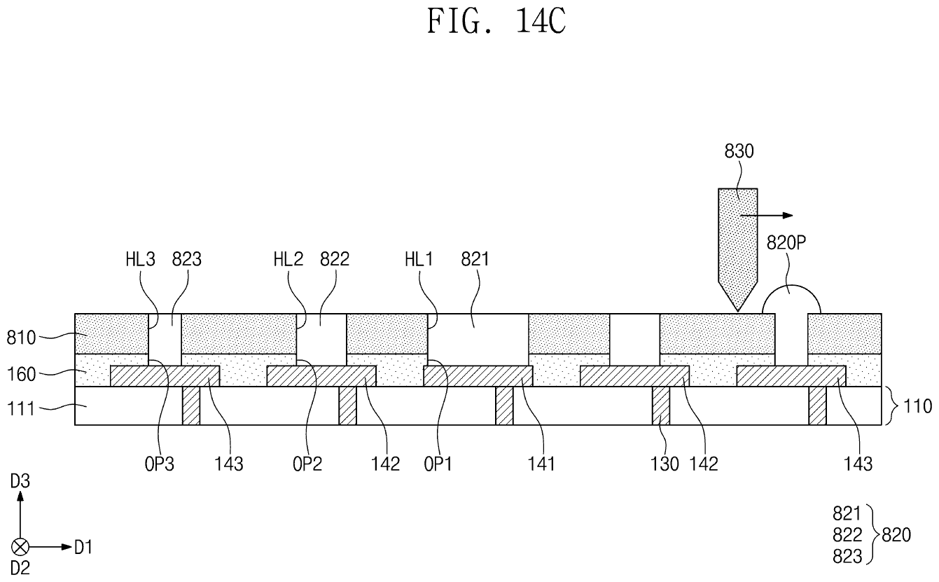

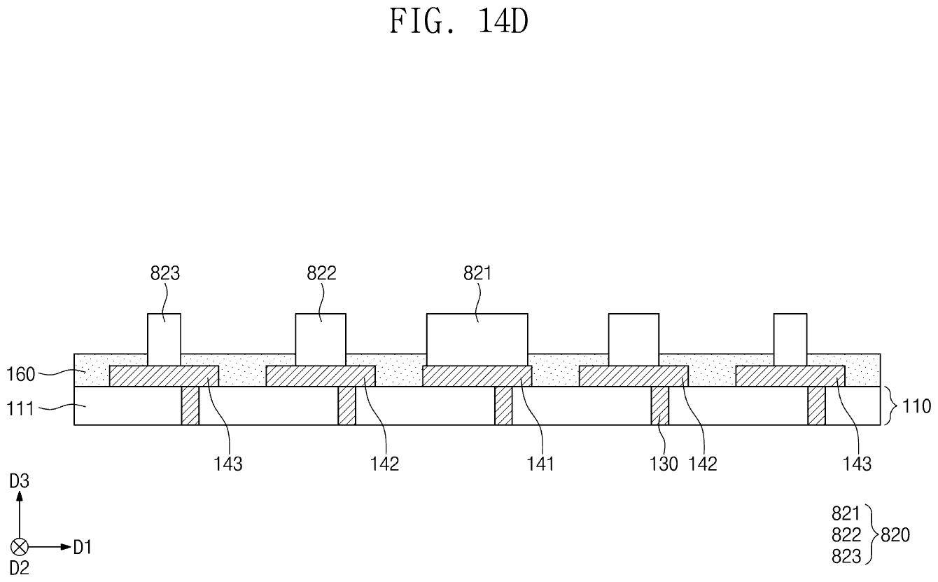

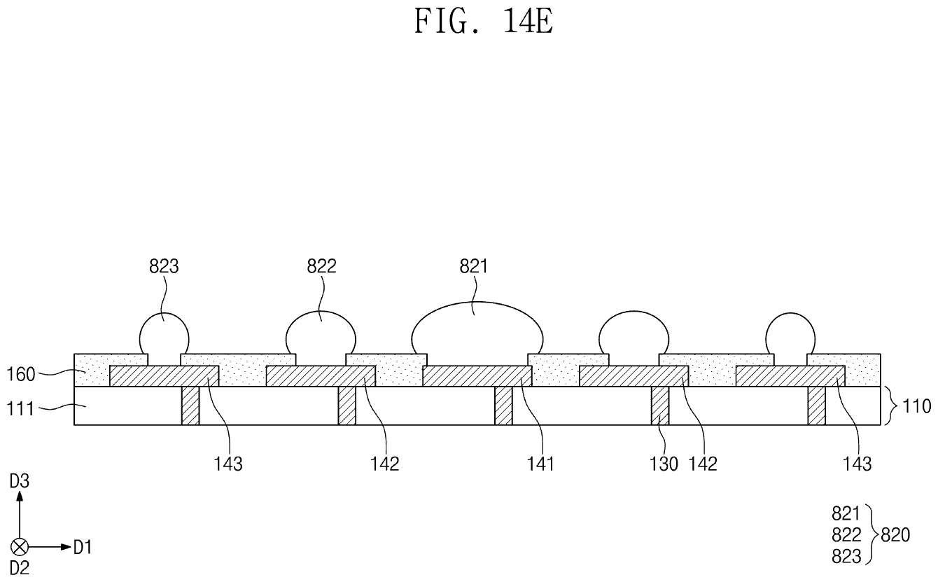

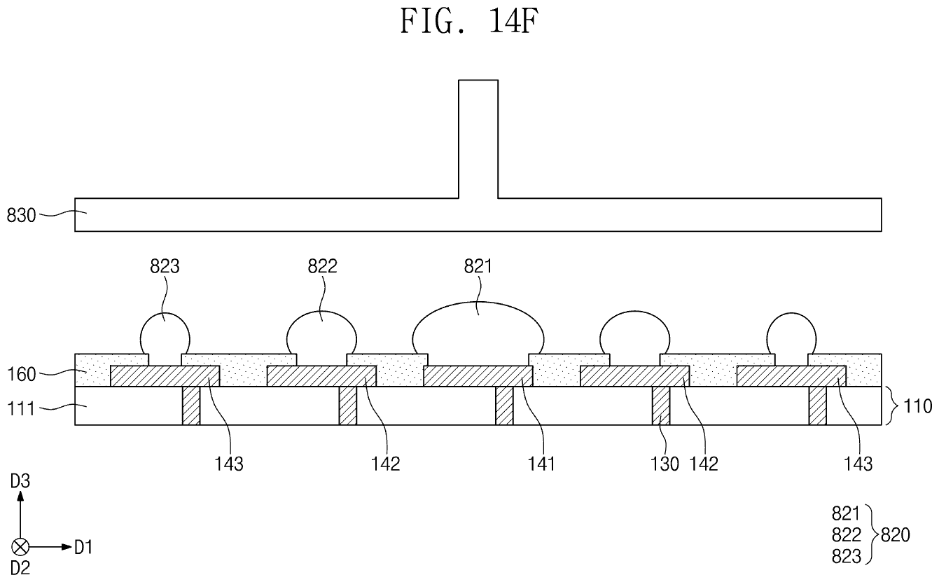

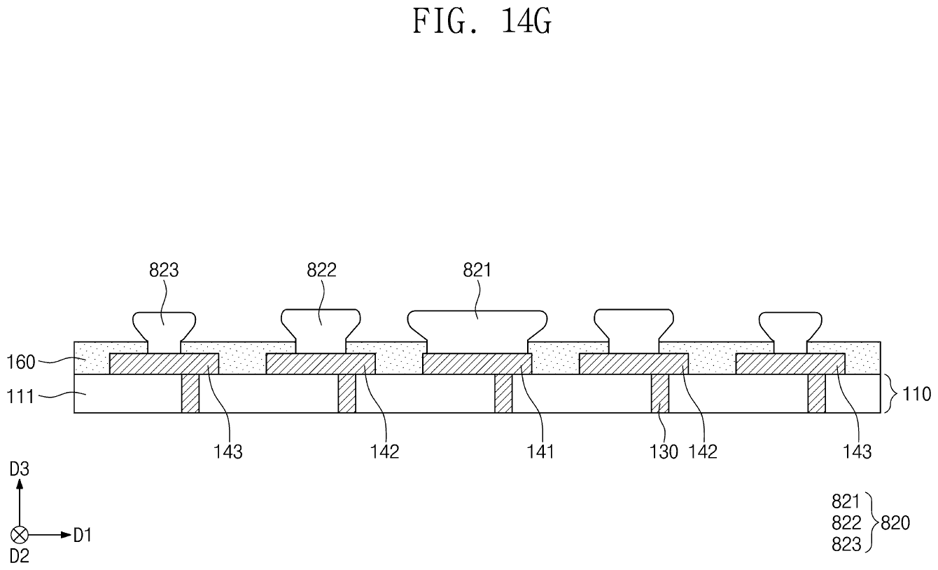

FIGS. 14A, 14B, 14C, 14D, 14E, and 14G are cross-sectional views illustrating a process of forming lower preliminary connection terminals on a package substrate.

Referring to FIG. 14A, a wiring layer 110 may be prepared. The wiring layer 110 may include an insulating layer 111, a wiring structure 130 in the insulating layer 111, and a substrate upper pads 140. The substrate upper pads 140 may include a first substrate pad 141, a second substrate pad 142, and a third substrate pad 143 exposed from the insulating layer 111.

Referring to FIG. 14B, an upper insulating layer 160 covering an upper surface of the wiring layer 110 and the substrate upper pads 140 may be formed. Forming the upper insulating layer 160 may include applying a solder resist on the upper insulating layer 160 and the substrate upper pads 140, exposing the photosensitive solder resist, and developing the exposed solder resist. The solder resist may include a photosensitive material. Through an exposure and development process, a first pad opening OP1 exposing the upper surface of the first substrate pad 141, a second pad opening OP2 exposing the upper surface of the second substrate pad 142, and a third pad opening OP3 exposing the upper surface of the third substrate pad 143 may be formed. A first exposed part 141E and a first covered part 141C of the first substrate pad 141 may be determined by the first pad opening OP1. Similarly, a second exposed part 142E and a second covered part 142C of the second substrate pad 142 may be determined by the second pad opening OP2, and a third exposed part 143E and a third covered part 143C of the third substrate pad 143 may be determined by the third pad opening OP3. By forming the upper insulating layer 160, the package substrate 100 may be formed.

Referring to FIG. 14C, a mask pattern 810 may be formed. Forming the mask pattern 810 may include preparing a metal sheet, forming holes (e.g., a first hole HL1, a second hole HL2, and a third hole HL3) by laser cutting or chemical etching. The mask pattern 810 may be, for example, a stencil. The mask pattern 810 may include a plurality of holes (e.g., the first hole HL1, the second hole HL2, and the third hole HL3). The holes may include a first hole HL1, a second hole HL2, and a third hole HL3.

The mask pattern 810 may be disposed on the package substrate 100. The mask pattern 810 may be disposed so that the first hole HL1 is connected to and overlapped with the first pad opening OP1 in the third direction D3. The mask pattern 810 may be disposed so that the second hole HL2 and the third hole HL3 also are connected to and overlapped with the second pad opening OP2 and the third pad opening OP3 in the third direction D3, respectively.

A solder paste 820P may be applied to fill the first to third holes HL1, HL2, and HL3 and the first to third pad openings OP1, OP2, and OP3. For example, the first to third holes HL1, HL2, and HL3 and the first to third pad openings OP1, OP2, and OP3 may be easily filled using a squeegee, and a portion of the solder paste 820P protruding above the upper surface of the mask pattern 810 may be removed. In this process, a thickness and a shape of the solder paste 820P, that is applied, may be accurately maintained, and lower preliminary connection terminals 820 may be formed. The lower preliminary connection terminals 820 may be preliminary connection terminals disposed below upper preliminary connection terminals 910 to be formed in the interposer 200, as will be described later.

The lower preliminary connection terminals 820 may include a first lower preliminary connection terminal 821 filling the first hole HL1 and the first pad opening OP1, a second lower preliminary connection terminal 822 filling the second hole HL2 and the second pad opening OP2, and a third lower preliminary connection terminal 823 filling the third hole HL3 and the third pad opening OP3.

Referring to FIG. 14D, the mask pattern 810 may be removed. As a result, an upper surface and side surfaces of the lower preliminary connection terminals 820 may be exposed to the outside. A thickness of the first lower preliminary connection terminal 821, a thickness of the second lower preliminary connection terminal 822, and a thickness of the third lower preliminary connection terminal 823 may be substantially the same as each other. A width of the first lower preliminary connection terminal 821 in the first direction D1 may be greater than a width of the second lower preliminary connection terminal 822 in the first direction D1 and a width of the third lower preliminary connection terminal 823 in the first direction D1. A width of the second lower preliminary connection terminal 822 in the first direction D1 may be greater than a width of the third lower preliminary connection terminal 823 in the first direction D1.

Referring to FIG. 14E, the lower preliminary connection terminals 820 may be deformed into a ball shape through a reflow process. In this case, a height of the lower preliminary connection terminals 820 may not be uniform, and an upper surface of the lower preliminary connection terminals 820 may have a curved surface.

Referring to FIGS. 14F and 14G, pressure may be applied to the upper surfaces of the lower preliminary connection terminals 820 to make the upper surfaces flat. The process of making the upper surfaces of the lower preliminary connection terminals 820 flat may include, for example, a coining process. A pressure device 830 may apply pressure to the lower preliminary connection terminals 820 that are ball-shaped. In this process, a height of the lower preliminary connection terminals 820 may become uniform, and upper surfaces thereof may become flat. The lower preliminary connection terminals 820 may also be referred to as first bumps.

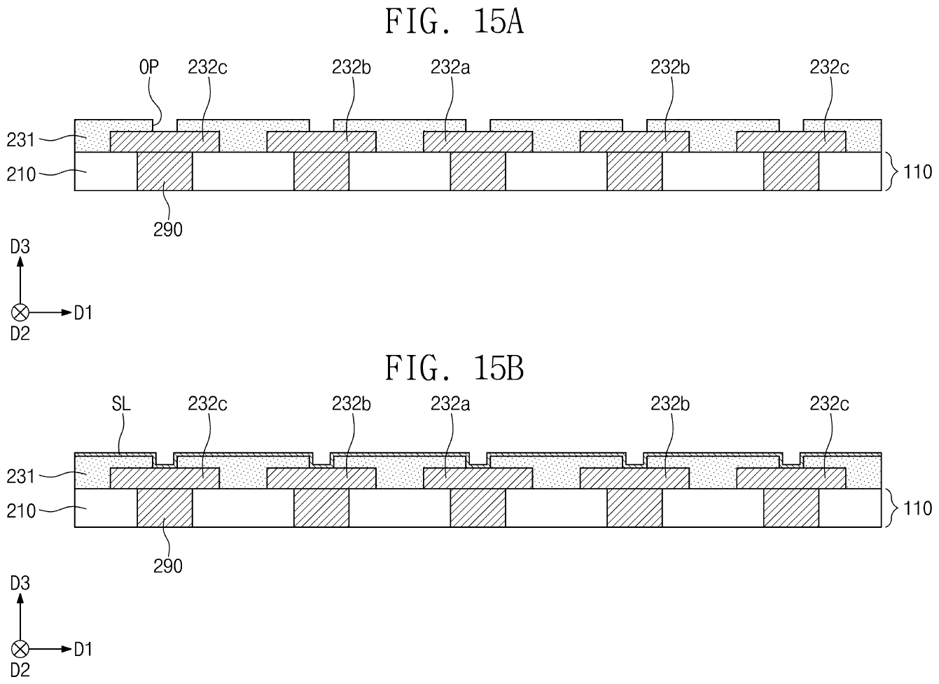

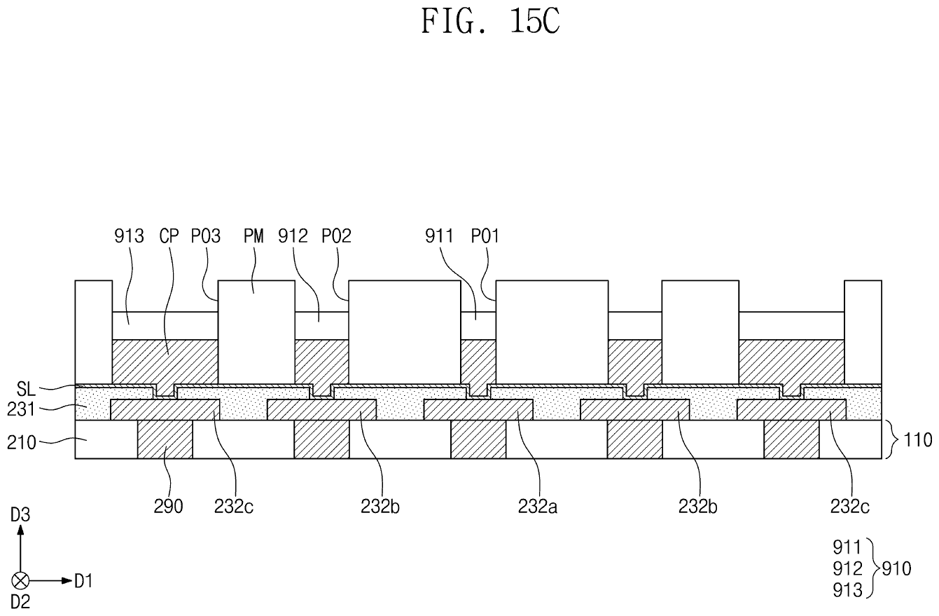

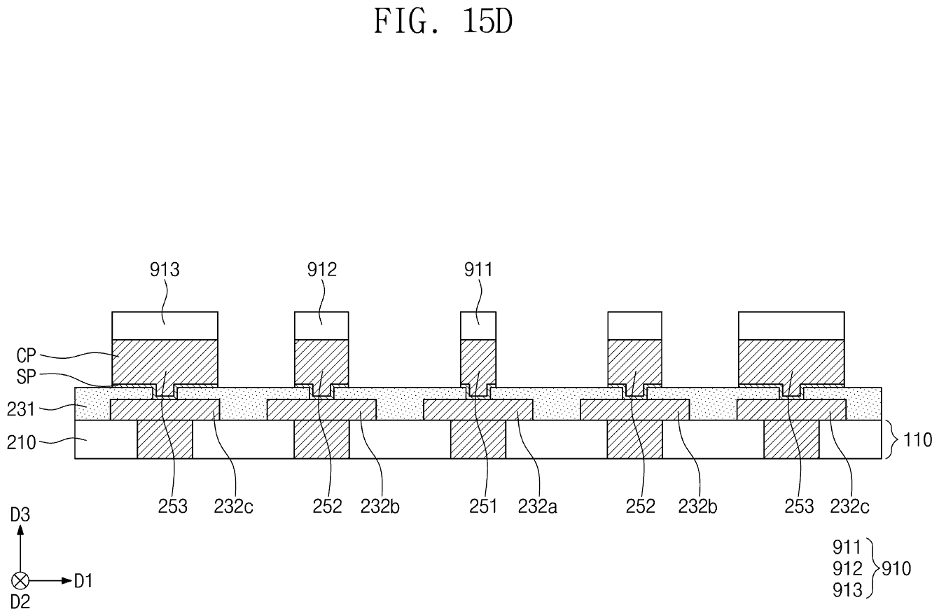

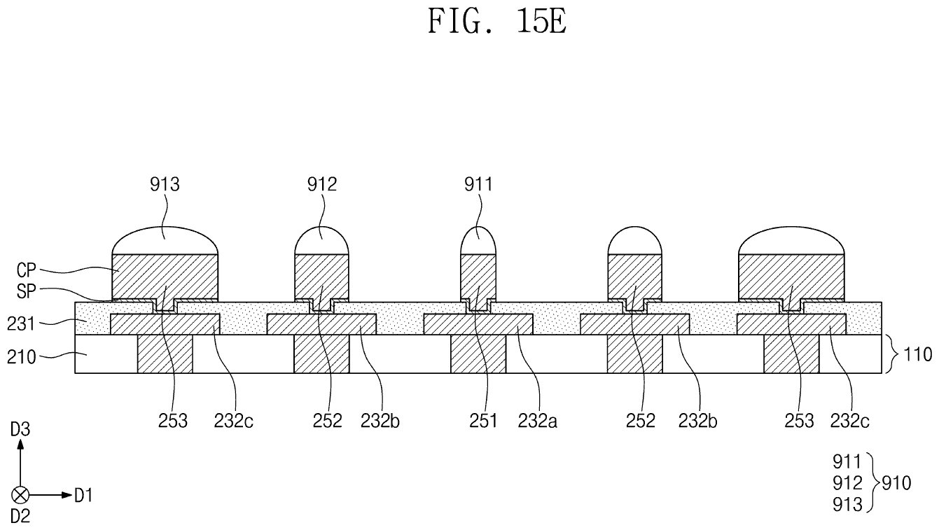

FIGS. 15A, 15B, 15C, 15D, and 15E are cross-sectional views illustrating a process of forming upper preliminary connection terminals on an interposer.

FIG. 15A illustrates the interposer 200 before the pillars are formed. A first connection pad 232a, a second connection pad 232b, and a third connection pad 232c may be respectively disposed on through vias 290 penetrating the semiconductor substrate 210. According to some embodiments, a second wiring structure 232 may be interposed between the through vias 290 and the first connection pad 232a, the second connection pad 232b, and the third connection pad 232c, and may include wiring lines and vias connecting the wiring lines. A second insulating layer 231 may be formed to cover the first connection pad 232a, the second connection pad 232b, the third connection pad 232c, and the semiconductor substrate 210. Forming the second insulating layer 231 may include depositing silicon oxide or silicon nitride, and forming openings OP through selective etching.

Referring to FIG. 15B, a seed layer SL may be formed on an upper surface of the second insulating layer 231 and an upper surfaces of the first connection pad 232a, the second connection pad 232b, and the third connection pad 232c that are exposed. Forming the seed layer SL may include forming a metal material using physical vapor deposition (PVD), chemical vapor deposition (CVD), or sputtering. The metal material may include at least one from among titanium, tungsten, and copper.

Referring to FIG. 15C, a photoresist pattern PM may be formed on the seed layer SL. Forming the photoresist pattern PM may include applying a photoresist on the seed layer SL, exposing the photoresist, and developing the exposed photoresist.

Through the exposure and development process, a first opening PO1 on the first connection pad 232a, a second opening P02 on the second connection pad 232b, and a third opening P03 on the third connection pad 232c may be formed. The first opening PO1, the second opening P02, and the third opening P03 may define regions where a first pillar 251, a second pillar 252, and a third pillar 253 are to be formed, respectively. A size of the first opening PO1 may be smaller than sizes of the second opening P02 and the third opening P03. A size of the second opening P02 may be smaller than a size of the third opening P03.

Conductive patterns CP may be formed on the seed layer SL by using an electroplating method using the seed layer SL as an electrode. The conductive patterns CP may be formed in the first opening PO1, the second opening P02, and the third opening P03, respectively. Then, upper preliminary connection terminals 910 may be formed on the conductive patterns CP using an electroplating method. The upper preliminary connection terminals 910 may include solder.

The upper preliminary connection terminals 910 may include a first upper preliminary connection terminal 911 formed in the first opening PO1, a second upper preliminary connection terminal 912 formed in the second opening P02, and a third upper preliminary connection terminal 913 formed in the third opening P03. A width of the first upper preliminary connection terminal 911 in the first direction D1 may be smaller than a width of the second upper preliminary connection terminal 912 in the first direction D1 and a width of the third upper preliminary connection terminal 913 in the first direction D1. A width of the second upper preliminary connection terminal 912 in the first direction D1 may be smaller than a width of the third upper preliminary connection terminal 913 in the first direction D1.

Referring to FIG. 15D, the seed layer SL may be patterned to form a seed pattern SP. As a result, the first pillar 251, the second pillar 252, and the third pillar 253 including the conductive pattern CP and the seed pattern SP may be formed. Patterning the seed layer SL may include selectively etching the seed layer SL using the upper preliminary connection terminal 910 and the conductive pattern CP as an etching mask.

Referring to FIG. 15E, the upper preliminary connection terminals 910 may be transformed into a ball shape or a hemispherical shape through a reflow process. In this case, an upper surface of the upper preliminary connection terminals 910 may have a curved surface. The upper preliminary connection terminal 910 may also be referred to as a second bump.

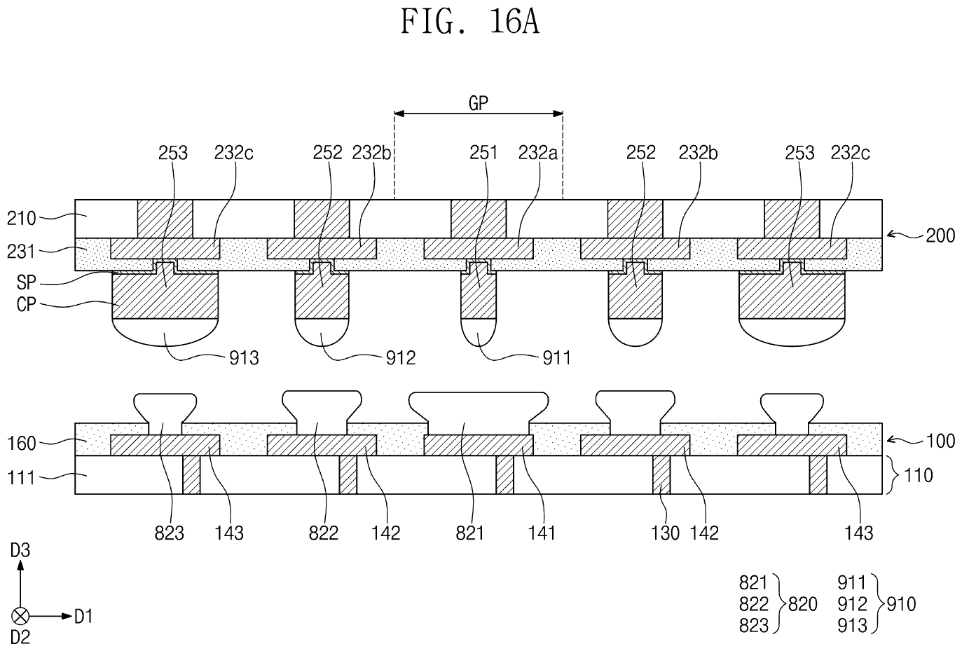

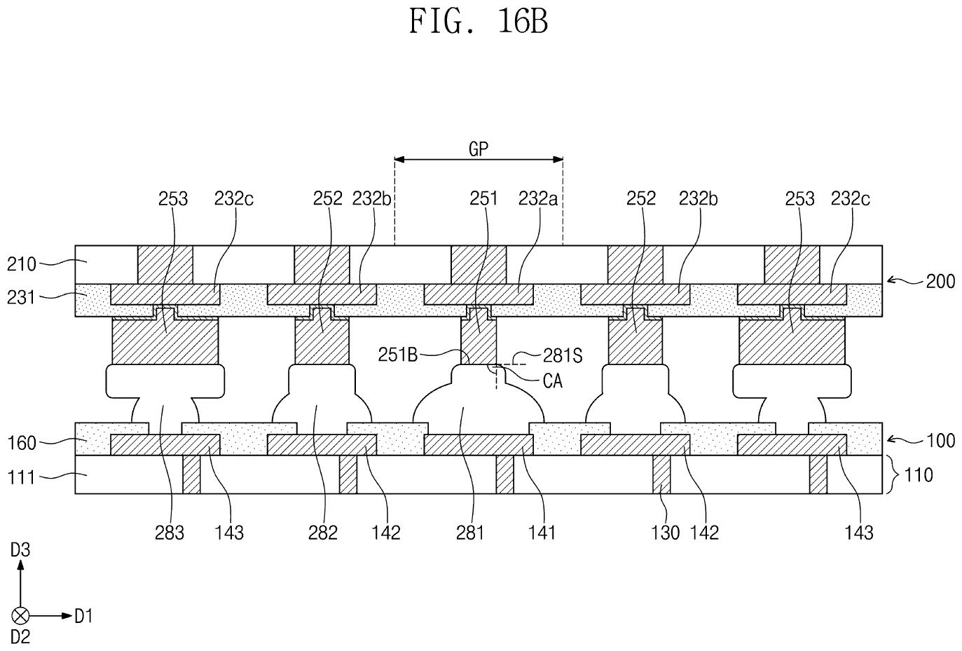

FIGS. 16A and 16B are cross-sectional views illustrating a process of mounting an interposer on a package substrate.

Referring again to FIGS. 1, 2, and 15E, a first semiconductor chip 300, a second semiconductor chip 400, and a third semiconductor chip 500 may be mounted on the interposer 200 as described with reference to FIGS. 1 and 2. Subsequently, a molding layer 900 covering the upper surface of the interposer 200, an upper surface and a side surface of the first semiconductor chip 300, an upper surface and a side surface of the second semiconductor chip 400, and an upper surface and a side surface of the third semiconductor chip 500 may be formed. The molding layer 900 may fill the gap GP between the first semiconductor chip 300 and the second semiconductor chip 400 and the gap GP between the first semiconductor chip 300 and the third semiconductor chip 500.

Referring to FIG. 16A, the interposer 200 may be placed on the package substrate 100 so that the lower preliminary connection terminals 820 and the upper preliminary connection terminals 910 are aligned with respect to each other in the third direction D3. Specifically, the first lower preliminary connection terminal 821 and the first upper preliminary connection terminal 911 may be aligned with respect to each other in the third direction D3, the second lower preliminary connection terminal 822 and the second upper preliminary connection terminal 912 may be aligned with respect to each other in the third direction D3, and the third lower preliminary connection terminal 823 and the third upper preliminary connection terminal 913 may be aligned with respect to each other in the third direction D3.

Referring to FIG. 16B, the interposer 200 may be mounted on the package substrate 100. The first lower preliminary connection terminal 821 may be in contact with the first upper preliminary connection terminal 911, the second lower preliminary connection terminal 822 may be in contact with the second upper preliminary connection terminal 912, and the third lower preliminary connection terminal 823 may be in contact with the third upper preliminary connection terminal 913.

The first lower preliminary connection terminal 821 and the first upper preliminary connection terminal 911 may be combined to form a first internal connection terminal 281. The second lower preliminary connection terminal 822 and the second upper preliminary connection terminal 912 may be combined to form a second internal connection terminal 282. The third lower preliminary connection terminal 823 and the third upper preliminary connection terminal 913 may be combined to form a third internal connection terminal 283.

According to embodiments of the present disclosure, a diameter of the first pillar 251 may be small, and a volume of the solder of the first lower preliminary connection terminal 821 may be large. The first internal connection terminal 281 having a large volume may be formed from the first lower preliminary connection terminal 821 having a large volume. In addition, the first pillar 251 having a small diameter may be formed so that the first internal connection terminal 281 extends onto the side surface of the first pillar 251 during the contact process between the first upper preliminary connection terminal 911 and the first lower preliminary connection terminal 821.

During the contact process between the first upper preliminary connection terminal 911 and the first lower preliminary connection terminal 821, a contact angle CA between a side surface 281S of the first internal connection terminal 281 and a lower surface 251B of the first pillar 251 may increase. For example, the contact angle CA during the contact between the first upper preliminary connection terminal 911 and the first lower preliminary connection terminal 821 may be at least 140° or more. When a diameter of the first pillar 251 is large, a volume of the solder of the first lower preliminary connection terminal 821 is small, and the contact angle CA is less than 140°, the first internal connection terminal 281 may not be attached to the side surface of the first pillar 251. The contact angle CA may continuously increase and may increase up to a maximum of 270°.

The semiconductor package according to embodiments of the present disclosure may include the small-diameter pillar of the interposer, and the large-volume connection terminal disposed between the pillar and the substrate pad of the package substrate. As a result, the electrical connection between the pillar and the substrate pad may be improved, and the non-wetting and short circuit may be prevented even when the warpage occurs. As a result, the allowable warpage in the manufacturing process of the semiconductor package may be increased, and the reliability of the semiconductor package may be improved.

While non-limiting example embodiments have been described above, a person skilled in the art may understand that many modifications and variations are made without departing from the spirit and scope of the present disclosure. Accordingly, the example embodiments of the present disclosure should be considered in all respects as illustrative and not restrictive.

What is claimed is:

1. A semiconductor package comprising:
a package substrate;
an interposer on the package substrate;
a first semiconductor chip on the interposer;
a second semiconductor chip on the interposer; and
a molding layer filling a portion between the first semiconductor chip and the second semiconductor chip,
wherein the interposer comprises a first pillar and a second pillar,
wherein the package substrate comprises a first substrate pad corresponding to the first pillar, and a second substrate pad corresponding to the second pillar,
wherein the package substrate comprises an insulating layer on a first portion of an upper surface of the first substrate pad and on a first portion of an upper surface of the second substrate pad,
wherein the package substrate further comprises a first connection terminal between the first pillar and the first substrate pad, and a second connection terminal between the second pillar and the second substrate pad,
wherein a diameter of the first pillar is smaller than a diameter of the second pillar, and
wherein a diameter of a second portion of the upper surface of the first substrate pad exposed from the insulating layer is greater than a diameter of a second portion of the upper surface of the second substrate pad exposed from the insulating layer.

2. The semiconductor package of claim 1, wherein the first connection terminal is in contact with a side surface of the first pillar.

3. The semiconductor package of claim 1, wherein the first pillar and the first substrate pad are below a gap between the first semiconductor chip and the second semiconductor chip.

4. The semiconductor package of claim 1, wherein a thickness of the first pillar in a vertical direction is greater than a thickness of the first substrate pad in the vertical direction.

5. The semiconductor package of claim 1, wherein a thickness of the first pillar in a vertical direction is the same as a thickness of the second pillar in the vertical direction.

6. The semiconductor package of claim 1, wherein the interposer is a silicon interposer or a redistribution interposer.

7. The semiconductor package of claim 1, wherein the interposer further comprises a redistribution substrate and a connection die in the redistribution substrate, and wherein the connection die comprises a semiconductor substrate.

8. The semiconductor package of claim 1, wherein the diameter of the first pillar is ¼ or less of the diameter of the second pillar, and
wherein the diameter of the first substrate pad is four times or more of the diameter of the second substrate pad.

9. The semiconductor package of claim 1, wherein a portion of the first pillar and a portion of the second pillar are at a lower surface of the interposer, and
wherein the first semiconductor chip and the second semiconductor chip are on an upper surface of the interposer.

10. The semiconductor package of claim 9, wherein the insulating layer comprises a solder resist.

11. The semiconductor package of claim 1, further comprises a third pillar between the first pillar and the second pillar,
wherein a diameter of the third pillar is greater than the diameter of the first pillar and smaller than the diameter of the second pillar.

12. The semiconductor package of claim 1, further comprising a third substrate pad between the first substrate pad and the second substrate pad,
wherein the insulating layer is on a first portion of an upper surface of the third substrate pad, and
wherein a diameter of a second portion of the upper surface of the third substrate pad exposed from the insulating layer is smaller than the diameter of the second portion of the upper surface of the first substrate pad exposed from the insulating layer and greater than the diameter of the second portion of the upper surface of the second substrate pad exposed from the insulating layer.

13. The semiconductor package of claim 1, wherein a maximum diameter of the first substrate pad is the same as a maximum diameter of the second substrate pad.

14. The semiconductor package of claim 1, wherein a level of an upper surface of the first connection terminal is higher than a level of a lower surface of the first pillar.

15. The semiconductor package of claim 1, wherein the diameter of the second portion of the upper surface of the first substrate pad exposed from the insulating layer is greater than the diameter of the first pillar.

16. A semiconductor package comprising:
a package substrate;
an interposer on the package substrate;
a first semiconductor chip on the interposer;
a second semiconductor chip on the interposer;
a molding layer filling a portion between the first semiconductor chip and the second semiconductor chip,
wherein the interposer comprises a first pillar and a second pillar,
wherein the package substrate comprises a first substrate pad corresponding to the first pillar and a second substrate pad corresponding to the second pillar,
wherein the package substrate further comprises a first connection terminal between the first pillar and the first substrate pad, and a second connection terminal between the second pillar and the second substrate pad,
wherein a diameter of the first pillar is smaller than a diameter of the second pillar, and
wherein a volume of the first connection terminal is greater than a volume of the second connection terminal.

17. The semiconductor package of claim 16, wherein each of the first connection terminal and the second connection terminal comprises solder.

18. The semiconductor package of claim 16, wherein, in a plan view, the first pillar is closer than the second pillar to a center of the interposer, and the first substrate pad is closer than the second substrate pad to a center of the package substrate.

19. A semiconductor package comprising:
a package substrate;
an interposer on the package substrate;
a first semiconductor chip on the interposer;
a second semiconductor chip on the interposer, and
a third semiconductor chip on the interposer; and
a molding layer on the first semiconductor chip, the second semiconductor chip, and the third semiconductor chip,
wherein the second semiconductor chip is spaced apart from the first semiconductor chip in a first direction parallel to an upper surface of the package substrate,
wherein the third semiconductor chip is spaced apart from the second semiconductor chip in a second direction perpendicular to the first direction and parallel to the upper surface of the package substrate,
wherein the interposer comprises a first pillar, a second pillar, and a third pillar spaced apart from each other in the first direction,
wherein the second pillar is between the first pillar and the third pillar,
wherein the package substrate comprises a first substrate pad corresponding to the first pillar, a second substrate pad corresponding to the second pillar, and a third substrate pad corresponding to the third pillar,
wherein the package substrate further comprises a first connection terminal between the first pillar and the first substrate pad, a second connection terminal between the second pillar and the second substrate pad, and a third connection terminal between the third pillar and the third substrate pad,
wherein a diameter of the first pillar is smaller than a diameter of the second pillar and a diameter of the third pillar,
wherein the diameter of the second pillar is smaller than the diameter of the third pillar,
wherein the first pillar is under a portion of the molding layer filling a gap between the first semiconductor chip and the second semiconductor chip or filling a gap between the first semiconductor chip and the third semiconductor chip, and
wherein, in a plan view, a size of the first semiconductor chip is greater than a size of the second semiconductor chip and a size of the third semiconductor chip.

20. The semiconductor package of claim 19, wherein an exposed diameter of the first substrate pad is greater than an exposed diameter of the second substrate pad, and the exposed diameter of the second substrate pad is smaller than an exposed diameter of the third substrate pad.
